(19) United States
(12) Patent Application Publication
(10) Pub. No.: US 2025/0231642 A1
(43) Pub. Date: Jul. 17, 2025

(54) DISPLAY PANEL AND DISPLAY DEVICE

(71) Applicant: Xiamen Tianma Microelectronics Co., Ltd., Xiamen (CN)

(72) Inventors: Hongan LIU, Xiamen (CN); Linqiong CAI, Xiamen (CN); Jiaqiang ZHENG, Xiamen (CN); Jiaqian WU, Xiamen (CN); Jiancai HUANG, Xiamen (CN); Xiaoxiao WU, Xiamen (CN)

(73) Assignee: Xiamen Tianma Microelectronics Co., Ltd., Xiamen (CN)

(21) Appl. No.: 19/170,847

(22) Filed: Apr. 4, 2025

(30) Foreign Application Priority Data
Dec. 23, 2024 (CN) 202411906820.7

(51) Int. Cl. G06F 3/041; G09G 3/20; H10F 39/10

(52) U.S. Cl. CPC G06F 3/0418; G06F 3/04164; G09G 3/20; H10F 39/103; G09G 2354/00; G09G 2360/144

(57) ABSTRACT

Provided are a display panel and a display device. The display panel includes a photosensitive module and a touch electrode line, where the photosensitive module includes a photosensitive transistor, a detection signal is applied to a first electrode of the photosensitive transistor, the photosensitive transistor is configured to generate a photocurrent signal according to the detection signal and illumination, and the touch electrode line is configured to transmit a touch signal. A driving stage of the display panel includes display stages and vertical intermittent stages, the display stages and the vertical intermittent stages are arranged alternately, and the vertical intermittent stages include touch stages. In multiple touch stages, the detection signal has a first voltage, and in at least one of the display stages, the detection signal has a second voltage, the second voltage is not equal to the first voltage.

### CROSS-REFERENCE TO RELATED APPLICATION(S)

This application claims priority of a Chinese Patent Application filed with China National Intellectual Property Administration (CNIPA) on Dec. 23, 2024, with application No. 202411906820.7, the disclosure of which is incorporated herein by reference in its entirety.

### TECHNICAL FIELD

The present disclosure relates to the field of display technology and, in particular, to a display panel and a display device.

### BACKGROUND

With the development of display technology, in a display panel, a photosensitive module is added for the display panel to adjust display brightness under different environmental brightness.

A touch noise phenomenon exists in the display panel provided with the photosensitive module.

### SUMMARY

The present disclosure provides a display panel and a display device to reduce a touch noise and ensure the touch performance of the display panel.

In a first aspect, embodiments of the present disclosure provide a display panel. The display panel includes a photosensitive module and a touch electrode line, the photosensitive module includes a photosensitive transistor, a detection signal is applied to a first electrode of the photosensitive transistor, the photosensitive transistor is configured to generate a photocurrent signal according to the detection signal and illumination, and the touch electrode line is configured to transmit a touch signal.

A driving stage of the display panel includes display stages and vertical intermittent stages, the display stages and the vertical intermittent stages are arranged alternately, and the vertical intermittent stages include touch stages.

In multiple touch stages, the detection signal has a first voltage, and in at least one of the display stages, the detection signal has a second voltage. The second voltage and the first voltage are not the same.

In a second aspect, embodiments of the present disclosure provide a display panel. The display panel includes a photosensitive module and a touch electrode line, the photosensitive module includes a photosensitive transistor, a detection signal is applied to a first electrode of the photosensitive transistor, the photosensitive transistor is configured to generate a photocurrent signal according to the detection signal and illumination, and the touch electrode line is configured to transmit a touch signal.

A driving stage of the display panel includes display stages and vertical intermittent stages, the display stages and the vertical intermittent stages are arranged alternately, and a vertical intermittent stage includes a touch stage and a light detection stage.

In multiple touch stages, the detection signal has a first voltage, and in at least one light detection stage, the detection signal has a second voltage. The second voltage is not identical to the first voltage.

In a third aspect, embodiments of the present disclosure provide a display device. The display device includes the display panel described in the first aspect or the second aspect.

### BRIEF DESCRIPTION OF DRAWINGS

To illustrate the technical solutions in embodiments of the present disclosure more clearly, drawings used in the description of the embodiments are briefly described hereinafter. Apparently, the drawings described hereinafter illustrate part of the embodiments of the present disclosure, and those of ordinary skill in the art may obtain other drawings based on the drawings described hereinafter on the premise that no creative work is done.

FIG. 1 is a structure diagram of a display panel according to an embodiment of the present disclosure.

FIG. 2 is a structure diagram of a photosensitive module according to an embodiment of the present disclosure.

FIG. 3 is a signal timing diagram according to an embodiment of the present disclosure.

FIG. 4 is another signal timing diagram according to an embodiment of the present disclosure.

FIG. 5 is another signal timing diagram according to an embodiment of the present disclosure.

FIG. 6 is another signal timing diagram according to an embodiment of the present disclosure.

FIG. 7 is another signal timing diagram according to an embodiment of the present disclosure.

FIG. 8 is another signal timing diagram according to an embodiment of the present disclosure.

FIG. 9 is another signal timing diagram according to an embodiment of the present disclosure.

FIG. 10 is another signal timing diagram according to an embodiment of the present disclosure.

FIG. 11 is another signal timing diagram according to an embodiment of the present disclosure.

FIG. 12 is another signal timing diagram according to an embodiment of the present disclosure.

FIG. 13 is another signal timing diagram according to an embodiment of the present disclosure.

FIG. 14 is another signal timing diagram according to an embodiment of the present disclosure.

FIG. 15 is another signal timing diagram according to an embodiment of the present disclosure.

FIG. 16 is another signal timing diagram according to an embodiment of the present disclosure.

FIG. 17 is another signal timing diagram according to an embodiment of the present disclosure.

FIG. 18 is an enlarged structure diagram of region S1 of FIG. 1.

FIG. 19 is a structure diagram of a display device according to an embodiment of the present disclosure.

### DETAILED DESCRIPTION

To make the technical solutions of the present disclosure better understood by those skilled in the art, the technical solutions in the embodiments of the present disclosure are described hereinafter clearly and completely in conjunction with the drawings in the embodiments of the present disclosure. Apparently, the embodiments described hereinafter are part, not all, of the embodiments of the present disclosure. Based on the embodiments of the present disclosure, all other embodiments obtained by those of ordinary skill in the art are within the scope of the present disclosure on the premise that no creative work is done.

It is to be noted that terms such as “first” and “second” in the description, claims, and drawings of the present disclosure are used for distinguishing between similar objects and are not necessarily used for describing a particular order or sequence. It is to be understood that data used in this manner are interchangeable where appropriate so that the embodiments of the present disclosure described herein can be implemented in an order not illustrated or described herein. In addition, the terms “including”, “having” or any other variations described herein are intended to encompass a non-exclusive inclusion. For example, a process, method, system, product or device that includes a series of steps or units may include not only the expressly listed steps or units but also other steps or units that are not expressly listed or are inherent to such a process, method, system, product or device.

Studies have found that a touch signal in a touch electrode line in a non-display region of a display panel is easily affected by the switching of a voltage signal in a detection signal line in a photosensitive module, resulting in the generation of a touch noise and a serious effect on a touch function of the display panel.

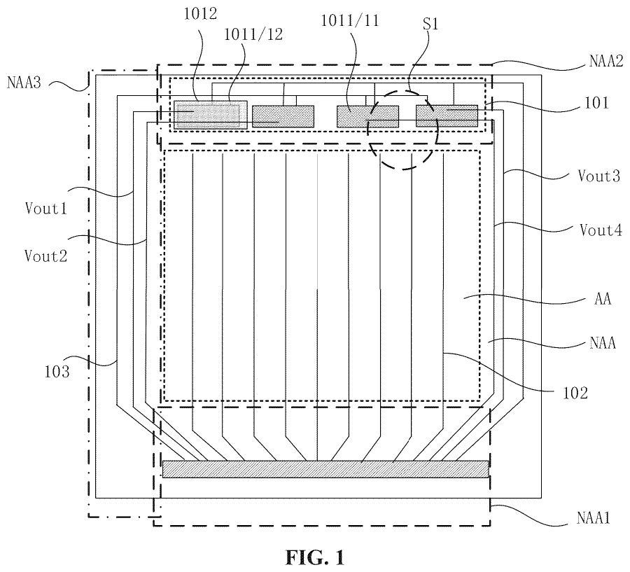

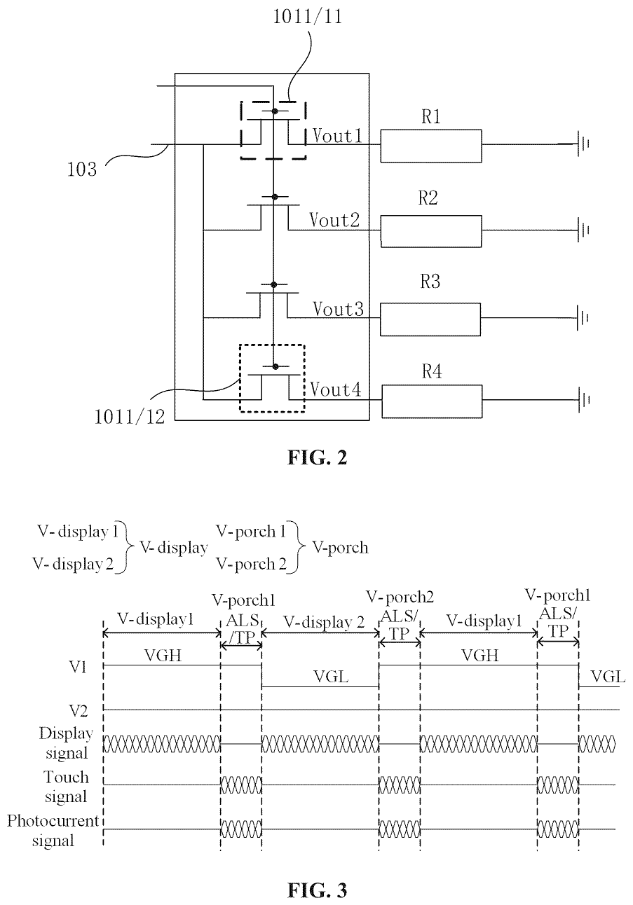

FIG. 1 is a structure diagram of a display panel according to an embodiment of the present disclosure. FIG. 2 is a structure diagram of a photosensitive module according to an embodiment of the present disclosure. FIG. 3 is a signal timing diagram according to an embodiment of the present disclosure. As shown in FIGS. 1, 2 and 3, the display panel includes a photosensitive module 101 and a touch electrode line 102. The photosensitive module 101 includes a photosensitive transistor 1011. A detection signal V1 is applied to a first electrode of the photosensitive transistor 1011, and the photosensitive transistor 1011 is configured to generate a photocurrent signal according to the detection signal V1 and illumination. The touch electrode line 102 is configured to transmit a touch signal. The touch signal may include a touch driving signal and/or a touch sensing signal. The touch driving signal is a driving signal transmitted to a touch electrode (not shown in FIG. 1) in a display region AA. The touch sensing signal is a sensing signal output by the touch electrode in the display region AA, and touch information is carried in the sensing signal.

A driving stage of the display panel includes display stages V-display and vertical intermittent stages V-porch, the display stages V-display and the vertical intermittent stages V-porch are arranged alternately, and a vertical intermittent stage V-porch is disposed between two adjacent display stages V-display. The display panel displays an image in the display stages V-display and does not display an image in the vertical intermittent stages V-porch. The vertical intermittent stage V-porch includes a touch stage TP, and the display panel implements a touch function in the touch stage TP. In the touch stage TP, the touch electrode line 102 transmits a touch signal. In a period other than the touch stage TP, the touch electrode line 102 may not transmit a touch signal.

In multiple touch stages TP, the detection signal V1 has a first voltage. In a feasible embodiment, in all touch stages TP, the detection signal V1 has the first voltage. In another feasible embodiment, in some touch stages TP, the detection signal V1 has the first voltage, and in other touch stages TP, the detection signal V1 has a voltage value different from the first voltage. It may be understood that in all the touch stages TP, when the detection signal V1 has the first voltage, not only an effect of preventing the detection signal V1 from causing the voltage jump of the touch signal in the touch electrode line 102, but also an effect of reducing or even avoiding the generation of the touch noise are beneficial. In at least one display stage V-display, the detection signal V1 has a second voltage, and the second voltage is not equal to the first voltage. In a feasible embodiment, in at least one display stage V-display, the detection signal V1 has another voltage value other than the second voltage.

As shown in FIGS. 1 and 2, the display panel includes the photosensitive module 101, and the photosensitive module 101 is disposed in a non-display region NAA. The photosensitive module 101 is used for sensing external ambient light and correspondingly adjusting the brightness change of the display panel according to the brightness change of the ambient light. The photosensitive module 101 includes the photosensitive transistor 1011, the first electrode of the photosensitive transistor 1011 may be a source, and a second electrode of the photosensitive transistor 1011 may be a drain. Alternatively, the first electrode of the photosensitive transistor 1011 may be a drain, and the second electrode of the photosensitive transistor 1011 may be a source. The second electrode of the photosensitive transistor 1011 is used for outputting the photocurrent signal, and a control signal V2 is applied to a gate of the photosensitive transistor 1011. The control signal V2 is generally a fixed potential signal. For example, the control signal V2 may be 1.5 V or a ground voltage. For example, the control signal V2 may be 0 V to 2 V. An active layer of the photosensitive transistor 1011 includes a photosensitive material layer so that some photosensitive transistors 1011 are configured to receive the illumination of ambient light to generate the photocurrent signal. Some photosensitive transistors 1011 are configured to output a reference signal in a dark state without ambient light to facilitate adjusting the display brightness of the display panel according to the photocurrent signal and the reference signal.

The touch electrode line 102 is further disposed in the display panel, and the touch signal is transmitted in the touch electrode line 102 to implement the touch function of the display panel. The driving stage of the display panel includes the display stage V-display and the vertical intermittent stage V-porch, that is, one frame is divided into the display stage V-display for displaying an image and the vertical intermittent stage V-porch for not displaying an image. In the current frame of the display panel, an end moment of the display stage V-display in the current frame is used as a start moment, a start moment of the display stage V-display in the next frame is used as an end moment, and a time difference value between the end moment and the start moment is used as the duration of the vertical intermittent stage V-porch in the current frame. It is to be noted that one frame here refers to a time period for refreshing one image. As shown in FIG. 1, in the non-display region NAA, some touch electrode lines 102 are relatively close to a detection signal line 103 for transmitting the detection signal V1, and when the detection signal V1 in the detection signal line 103 is subjected to a voltage jump, coupling occurs between the detection signal line 103 and the touch electrode line 102, resulting in a touch noise in the display panel. Generally, a touch stage TP is located in a vertical intermittent stage V-porch between adjacent display stages V-display. In multiple touch stages TP, the detection signal V1 has the first voltage so that the detection signal V1 has the same voltage value in the multiple touch stages TP, and the voltage value of the detection signal V1 is prevented from being switched back and forth in the multiple touch stages TP. Therefore, in the touch stage TP, the touch signal transmitted by the touch electrode line 102 is not affected by the voltage jump of the detection signal V1, thereby reducing or even avoiding the noise generated by the touch signal.

For example, as shown in FIG. 3, the first voltage of the detection signal V1 in multiple touch stages TP is a gate control positive voltage VGH, and the second voltage in some display stages V-display is a gate control negative voltage VGL. A voltage value of the gate control positive voltage VGH is greater than 0, and a voltage value of the gate control negative voltage VGL is less than 0. The display panel includes a pixel driving circuit, and the pixel driving circuit includes a thin-film transistor. The gate control positive voltage VGH and the gate control negative voltage VGL are applied to a gate of the thin-film transistor and are configured to control the thin-film transistor to turn on or off. For an N-type thin-film transistor, the gate control positive voltage VGH is configured to control the thin-film transistor to turn on, and the gate control negative voltage VGL is configured to control the thin-film transistor to turn off. For a P-type thin-film transistor, the gate control positive voltage VGH is configured to control the thin-film transistor to turn off, and the gate control negative voltage VGL is configured to control the thin-film transistor to turn on. The detection signal V1 in display stages V-display in different frames may have a voltage jump. When the second voltage of the detection signal V1 in the display stage V-display is the gate control positive voltage VGH, a threshold voltage of the photosensitive transistor 1011 is positively drifted. When the second voltage of the detection signal V1 in the display stage V-display is the gate control negative voltage VGL, the threshold voltage of the photosensitive transistor 1011 is negatively drifted. In this manner, the threshold voltage drift of the photosensitive transistor 1011 can be reduced under a combined action of the gate control positive voltage VGH and the gate control negative voltage VGL and the stability of the photosensitive transistor 1011 can be ensured.

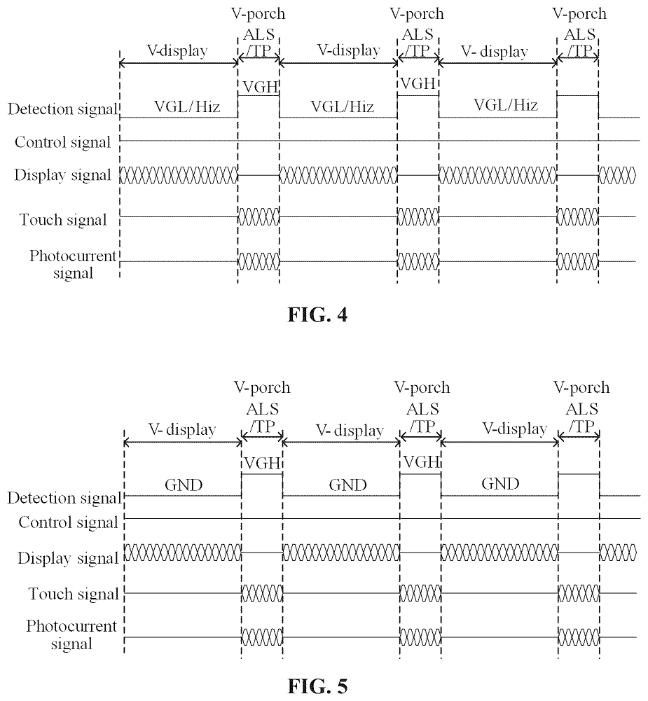

FIG. 4 is another signal timing diagram according to an embodiment of the present disclosure. As shown in FIG. 4, in multiple touch stages TP, the first voltage of the detection signal V1 is the gate control positive voltage VGH. The second voltage in multiple display stages V-display is the gate control negative voltage VGL or in a high-impedance state Hiz. In the multiple touch stages TP, the first voltage of the detection signal V1 remains consistent and is not subjected to the voltage jump, and the touch signal transmitted by the touch electrode line 102 is not affected by the voltage jump of the detection signal V1, thereby reducing or even avoiding the noise generated by the touch signal. In the multiple display stages V-display, the second voltage of the detection signal V1 maintains as VGL or in the high-impedance state Hiz instead of continuously setting the detection signal V1 to the gate control positive voltage VGH, to prevent the photosensitive transistor 1011 from continuously working in the same direction in different stages or prevent the photosensitive transistor 1011 from continuously applying the gate control positive voltage VGH to the first electrode of the photosensitive transistor 1011 in different stages, thereby reducing the threshold voltage drift of the photosensitive transistor 1011.

FIG. 5 is another signal timing diagram according to an embodiment of the present disclosure. As shown in FIG. 5, the first voltage of the detection signal V1 in multiple touch stages TP is the gate control positive voltage VGH, and the second voltage of the detection signal V1 in multiple display stages V-display is a ground voltage GND. In the multiple touch stages TP, the first voltage of the detection signal V1 remains consistent and is not subjected to the voltage jump, and the touch signal transmitted by the touch electrode line 102 is not affected by the voltage jump of the detection signal V1, thereby reducing or even avoiding the noise generated by the touch signal. In the multiple display stages V-display, the second voltage of the detection signal V1 is the ground voltage GND to prevent the photosensitive transistor 1011 from continuously applying a gate control positive voltage VGH to the first electrode of the photosensitive transistor 1011 in different stages, thereby reducing the threshold voltage drift of the photosensitive transistor 1011.

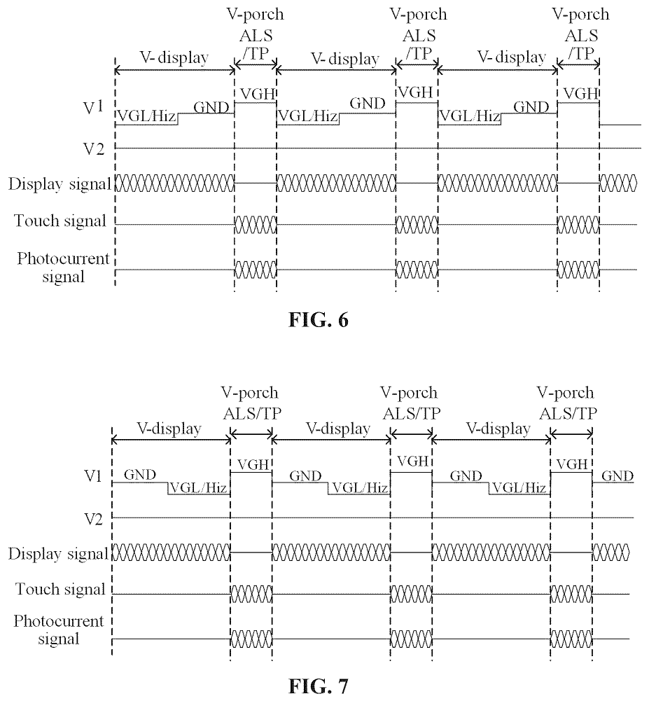

FIG. 6 is another signal timing diagram according to an embodiment of the present disclosure. FIG. 7 is another signal timing diagram according to an embodiment of the present disclosure. As shown in FIGS. 6 and 7, the first voltage of the detection signal V1 in multiple touch stages TP is the gate control positive voltage VGH, one portion of the second voltage of the detection signal V1 in the same display stage V-display is the gate control negative voltage VGL or in the high-impedance state Hiz, the other portion of the second voltage is the ground voltage GND, the second voltage of the detection signal V1 in the same display stage V-display jumps, and the second voltage in multiple display stages V-display jumps in the same manner. As shown in FIG. 6, the second voltage of the detection signal V1 in the display stage V-display is firstly maintained as the gate control negative voltage VGL or in the high-impedance state Hiz, and then the second voltage of the detection signal V1 is switched to the ground voltage GND. As shown in FIG. 7, the second voltage of the detection signal V1 in the display stage V-display is firstly maintained as the ground voltage GND, and then the second voltage of the detection signal V1 is switched to the gate control negative voltage VGL or in the high-impedance state Hiz. In the multiple touch stages TP, the first voltage of the detection signal V1 remains consistent and is not subjected to the voltage jump, and the touch signal transmitted by the touch electrode line 102 is not affected by the voltage jump of the detection signal V1, thereby reducing or even avoiding the noise generated by the touch signal. In the multiple display stages V-display, the second voltage of the detection signal V1 maintains as the gate control negative voltage VGL or in the high-impedance state Hiz and as the ground voltage GND instead of continuously setting the detection signal V1 as the gate control positive voltage VGH to prevent the photosensitive transistor 1011 from continuously working in the same direction in different stages or prevent the photosensitive transistor 1011 from continuously applying the gate control positive voltage VGH to the first electrode of the photosensitive transistor 1011 in different stages, thereby reducing the threshold voltage drift of the photosensitive transistor 1011.

In the display panel provided by the embodiments of the present disclosure, the detection signal V1 is applied to the first electrode of the photosensitive transistor 1011 of the photosensitive module 101, the photocurrent signal is generated in combination with the illumination, and the display brightness of the display panel is adjusted under different environmental brightness. The driving stage of the display panel includes the display stage V-display and the vertical intermittent stage V-porch that are arranged alternately. The vertical intermittent stage V-porch includes the touch stage TP, and the detection signal V1 in multiple touch stages TP has the same first voltage, thereby avoiding a coupling effect on the touch signal in the touch electrode line 102 caused by the voltage jump of the detection signal V1 and reducing or even avoiding the generation of the touch noise. The first voltage of the detection signal V1 in the touch stage TP is different from the second voltage of the detection signal V1 in at least one display stage V-display, and the detection signal V1 in different display stages V-display has a voltage jump, thereby reducing or even avoiding the threshold voltage drift of the photosensitive transistor 1011, ensuring the stable operation of the photosensitive transistor 1011 and improving the accuracy of the photosensitive collection.

Referring to FIG. 3, the vertical intermittent stages V-porch further include light detection stages ALS, and a light detection stage ALS is disposed in a vertical intermittent stage V-porch. In the light detection stage ALS, the photocurrent signal is acquired, and the intensity of the ambient light is acquired according to the photocurrent signal to adjust the brightness of the display panel according to the brightness of the ambient light. In the light detection stage ALS, the detection signal V1 has the first voltage. In the light detection stage ALS and the touch stage TP, the detection signal V1 has the first voltage, and the voltage value of the detection signal V1 remains unchanged. The photocurrent signal is collected in the vertical intermittent stage V-porch, and the brightness of the display panel is adjusted.

Referring to FIG. 3, the light detection stage ALS overlaps the touch stage TP. The light detection stage ALS and the touch stage TP have an overlapping period in which both the photocurrent signal and the touch signal are collected. Therefore, the duration occupied by both the light detection stage ALS and the touch stage TP can be reduced, the duration of the vertical intermittent stage V-porch can be reduced, and the display frequency can be improved.

Referring to FIG. 3, the first voltage and the second voltage have opposite polarities. The first voltage is a voltage of positive polarity, that is, a positive voltage. The second voltage is a voltage of negative polarity, that is, a negative voltage. In other embodiments, the first voltage may be a voltage of negative polarity, and the second voltage may be a voltage of positive polarity. In multiple touch stages TP, the detection signal V1 maintains the same first voltage, thereby reducing or even avoiding the touch noise generated by the touch signal in the touch electrode line 102 due to the voltage jump of the detection signal V1. The detection signal V1 in some display stages V-display has the second voltage so that the second voltage and the first voltage have opposite polarities. For example, the first voltage may be positive, and the second voltage may be negative; alternatively, the first voltage may be negative, and the second voltage may be positive. The detection signal V1 in adjacent display stages V-display is subjected to voltage jump, thereby effectively reducing the threshold voltage drift of the photosensitive transistor 1011, ensuring the operational stability of the photosensitive transistor 1011 and improving the brightness adjustment accuracy of the display panel.

Referring to FIG. 3, multiple display stages V-display include first display stages V-display1 and second display stages V-display2, and the first display stages V-display1 and the second display stages V-display2 are arranged alternately. In the first display stages V-display1, the detection signal V1 has the first voltage, and in the second display stages V-display2, the detection signal V1 has the second voltage. When the detection signal V1 always remains working in the same direction in the display stages V-display, the photosensitive transistor 1011 is prone to a threshold voltage drift, the detection signal V1 in adjacent display stages V-display is adjusted for voltage switching, the first voltage of the detection signal V1 in the first display stage V-display1 is not equal to the second voltage of the detection signal V1 in the second display stage V-display2, and the threshold voltage drift degree of the photosensitive transistor 1011 is reduced to improve the accuracy of photosensitive collection.

Referring to FIG. 3, for the photosensitive transistor 1011, the first voltage of the detection signal V1 in the first display stage V-display1 is the gate control positive voltage VGH, for example, 15 V; the second voltage of the detection signal V1 in the second display stage V-display2 is the gate control negative voltage VGL, for example, −15 V. An absolute value of the first voltage is equal to an absolute value of the second voltage so that a threshold voltage drift direction of the photosensitive transistor 1011 in the first display stage V-display1 is opposite to a threshold voltage drift direction of the photosensitive transistor 1011 in the second display stage V-display2, and in combination with the alternating arrangement of the first display stages V-display1 and the second display stages V-display2, the threshold voltage of the photosensitive transistor 1011 remains stable, thereby ensuring the collection accuracy of the photocurrent signal and further improving the brightness adjustment accuracy of the display panel.

In one or more embodiments, referring to FIG. 3, multiple display stages V-display include first display stages V-display1 and second display stages V-display2, and multiple vertical intermittent stages V-porch include first vertical intermittent stages V-porch1 and second vertical intermittent stages V-porch2. The first display stage V-display1, the first vertical intermittent stage V-porch1, the second display stage V-display2 and the second vertical intermittent stage V-porch2 are arranged in sequence. A voltage of the detection signal V1 in the first vertical intermittent stage V-porch1 is adjusted to be the same as a voltage of the detection signal V1 in the first display stage V-display1, and the second voltage of the detection signal V1 in the first display stage V-display1 is identical to the first voltage of the detection signal V1 in the first vertical intermittent stage V-porch1. The second voltage of the detection signal V1 in the second display stage V-display2 is not identical to the first voltage of the detection signal V1 in the second vertical intermittent stage V-porch2. In the light detection stage ALS of the first vertical intermittent stage V-porch1, the photocurrent signal is collected, and the detection signal V1 in the light detection stage ALS is the gate control positive voltage VGH, thereby facilitating that a driver chip collects and identifies the photocurrent signal generated by the photosensitive transistor 1011 and performs frame skipping collection on the photocurrent signal to ensure the uniformity of the photosensitive collection and improve the brightness adjustment accuracy of the display panel.

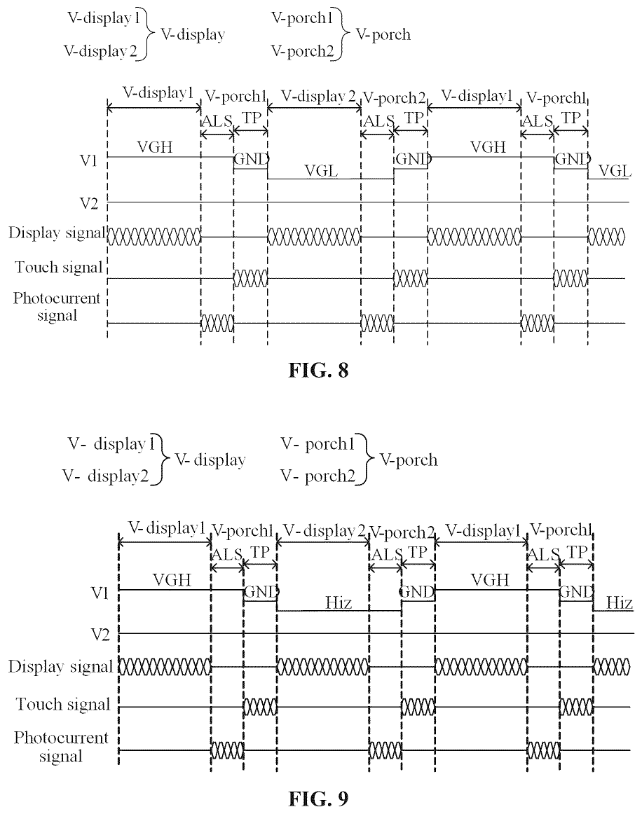

FIG. 8 is another signal timing diagram according to an embodiment of the present disclosure. As shown in FIG. 8, the light detection stage ALS is set in the vertical intermittent stage V-porch. In the light detection stage ALS, the photocurrent signal is acquired, and the intensity of the ambient light is acquired according to the photocurrent signal to adjust the brightness of the display panel according to the brightness of the ambient light. In the light detection stage ALS, the detection signal V1 has the second voltage. For example, the first voltage of the detection signal V1 is the ground voltage GND in the touch stage TP, and the second voltage of the detection signal V1 is the gate control positive voltage VGH in the light detection stage ALS; in this case, the touch stage TP and the light detection stage ALS in the vertical intermittent stage V-porch do not overlap and are distributed in two independent time periods to ensure a touch effect. In multiple touch stages TP, the detection signal V1 has the first voltage to prevent the voltage adjustment of the detection signal V1 from generating the touch noise. The photocurrent signal is collected in the light detection stage ALS of the vertical intermittent stage V-porch so that the brightness of the display panel is adjusted. The durations of multiple driving stages of the display panel may also be adjusted to be consistent, thereby ensuring a display effect.

Referring to FIG. 8, multiple display stages V-display include first display stages V-display1 and second display stages V-display2, and the first display stages V-display1 and the second display stages V-display2 are arranged alternately; in the first display stages V-display1, the detection signal V1 has the second voltage, and in the second display stages V-display2, the detection signal V1 has a third voltage. The first voltage, the second voltage and the third voltage are not identical. For example, as shown in FIG. 8, the first voltage is the ground voltage GND, the second voltage is the gate control positive voltage VGH, and the third voltage is the gate control negative voltage VGL. In adjacent display stages V-display, the detection signal V1 is subjected to a voltage jump to prevent continuously applying the gate control positive voltage VGH to the first electrode of the photosensitive transistor 1011 in different stages, thereby reducing the threshold voltage drift of the photosensitive transistor 1011. The detection signal V1 in the touch stage TP of the vertical intermittent stage V-porch has the first voltage and is not subjected to the voltage jump so that the touch signal transmitted by the touch electrode line 102 is not affected by the voltage jump of the detection signal V1, thereby reducing or even avoiding the noise generated by the touch signal.

Referring to FIG. 8, the second voltage is greater than the third voltage; an absolute value of the second voltage is equal to an absolute value of the third voltage, and the second voltage and the third voltage have opposite polarities; or the third voltage is in the high-impedance state Hiz. In adjacent display stages V-display, a voltage of the detection signal V1 needs to jump. At present, the output of a pin of the driver chip is needed for implementing voltage switching, and the driver chip can output the gate control positive voltage VGH, the gate control negative voltage VGL, the ground voltage GND and the high-impedance state Hiz.

For example, as shown in FIG. 8, the first voltage is the ground voltage GND, the second voltage is the gate control positive voltage VGH, and the third voltage is the gate control negative voltage VGL. The detection signal V1 is subjected to voltage switching in a first display stage V-display1 and a second display stage V-display2 that are adjacent to each other, an absolute value of the second voltage of the detection signal V1 in the first display stage V-display1 is equal to an absolute value of the third voltage of the detection signal V1 in the second display stage V-display2, and the second voltage and the third voltage have opposite polarities. In the first display stage V-display1, the detection signal V1 causes the threshold voltage of the photosensitive transistor 1011 to positively drift, and in the second display stage V-display2, the detection signal V1 causes the threshold voltage of the photosensitive transistor 1011 to negatively drift. The threshold voltage drift of the photosensitive transistor 1011 can be reduced under a combined action of the two voltages of the detection signal V1 and the stability of the photosensitive transistor 1011 can be ensured.

FIG. 9 is another signal timing diagram according to an embodiment of the present disclosure. As shown in FIG. 9, reference is made to the case where the second voltage is greater than the third voltage or the third voltage is in the high-impedance state Hiz. For example, the first voltage is the ground voltage GND, the second voltage is the gate control positive voltage VGH, and the third voltage is the high-impedance state Hiz. The detection signal V1 is subjected to voltage switching in a first display stage V-display1 and a second display stage V-display2 that are adjacent to each other, and the second voltage of the detection signal V1 in the first display stage V-display1 is not equal to the third voltage of the detection signal V1 in the second display stage V-display2. In the second display stage V-display2, the second voltage of the detection signal V1 maintains in the high-impedance state Hiz instead of continuously setting the detection signal V1 to the gate control positive voltage VGH, the photosensitive transistor 1011 is prevented from continuously applying the gate control positive voltage VGH to the first electrode of the photosensitive transistor 1011 in different stages, thereby reducing the threshold voltage drift of the photosensitive transistor 1011.

Referring to FIG. 8, multiple vertical intermittent stages V-porch include first vertical intermittent stages V-porch1 and second vertical intermittent stages V-porch2, and the first display stage V-display1, the first vertical intermittent stage V-porch1, the second display stage V-display2 and the second vertical intermittent stage V-porch2 are arranged in sequence; in the first vertical intermittent stage V-porch1, the detection signal V1 has the second voltage, and in the second vertical intermittent stage V-porch2, the detection signal V1 has the third voltage. The voltage of the detection signal V1 in the first vertical intermittent stage V-porch1 is the same as the voltage of the detection signal V1 in the first display stage V-display1, and the voltage of the detection signal V1 in the second vertical intermittent stage V-porch2 is the same as the voltage of the detection signal V1 in the second display stage V-display2. For example, the second voltage is the gate control positive voltage VGH, and the third voltage is the gate control negative voltage VGL so that the occupation duration of the gate control positive voltage VGH is the same as the occupation duration of the gate control negative voltage VGL, the gate control positive voltage VGH causes the threshold voltage of the photosensitive transistor 1011 to drift positively, the gate control negative voltage VGL causes the threshold voltage of the photosensitive transistor 1011 to drift negatively, and the gate control positive voltage VGH and the gate control negative voltage VGL have opposite effects on the threshold voltage drift of the photosensitive transistor 1011. When the duration of the gate control positive voltage VGH is equal to the duration of the gate control negative voltage VGL, the threshold voltage drift of the photosensitive transistor 1011 is reduced or even avoided, thereby ensuring the stability of the photosensitive transistor 1011.

Referring to FIG. 8, the light detection stage ALS in the first vertical intermittent stage V-porch1 is located between the touch stage TP in the first vertical intermittent stage V-porch1 and the first display stage V-display1; the detection signal V1 in the first display stage V-display1 and the light detection stage ALS maintains the second voltage, and after the first display stage V-display1 is completed, the light detection stage ALS may be directly entered, thereby reducing the number of voltage jumps of the detection signal V1 and reducing the operation difficulty of the driver chip.

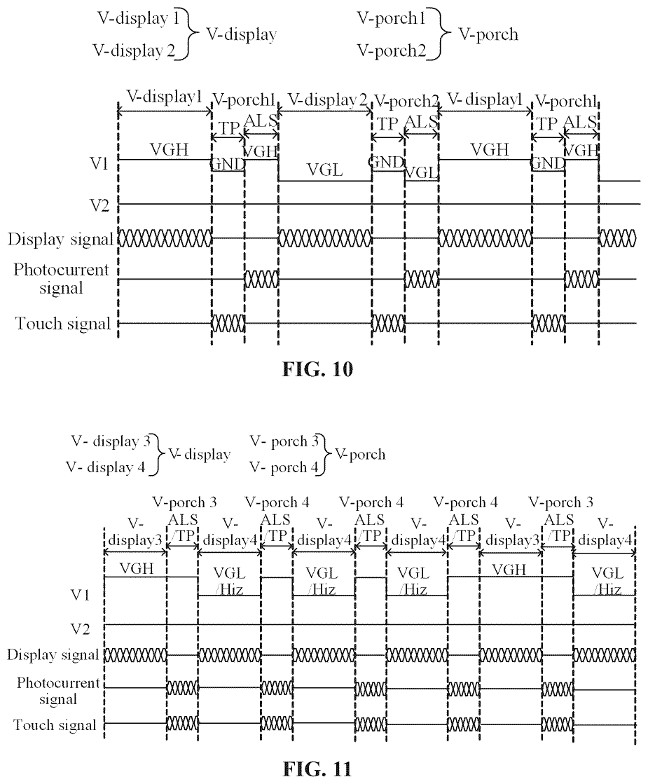

FIG. 10 is another signal timing diagram according to an embodiment of the present disclosure. As shown in FIG. 10, a light detection stage ALS in the second vertical intermittent stage V-porch2 is located between a touch stage TP in the second vertical intermittent stage V-porch2 and the second display stage V-display2. After the first display stage V-display1 is completed, the touch stage TP is entered to switch the voltage of the detection signal V1 to prevent the photosensitive transistor 1011 from continuously working in the same direction in different stages, thereby reducing the threshold voltage drift of the photosensitive transistor 1011.

With continued reference to FIGS. 8 and 9, the first voltage is applied to the first electrode of the photosensitive transistor 1011 in the touch stage TP. The first voltage is the ground voltage GND, and no drift is caused to the threshold voltage of the photosensitive transistor 1011, thereby ensuring the stability of the photosensitive transistor 1011. In the touch stage TP, the first voltage of the detection signal V1 remains unchanged, and the touch signal transmitted by the touch electrode line 102 is subjected to no voltage switching of the detection signal V1, thereby reducing or even avoiding the touch noise. The second voltage of the detection signal V1 in the first display stage V-display1 is the gate control positive voltage VGH, and the second voltage of the detection signal V1 in the light detection stage ALS of the first vertical intermittent stage V-porch1 is the gate control positive voltage VGH. The second voltage of the detection signal V1 in the second display stage V-display2 is the gate control negative voltage VGL, and the second voltage of the detection signal V1 in the light detection stage ALS of the second vertical intermittent stage V-porch2 is the gate control negative voltage VGL. In the display stage V-display and the light detection stage ALS, the voltage can be reversed frame by frame so that the occupation duration of the gate control positive voltage VGH is equal to the occupation duration of the gate control negative voltage VGL. When the duration of the gate control positive voltage VGH is equal to the duration of the gate control negative voltage VGL, the threshold voltage drift of the photosensitive transistor 1011 is reduced or even avoided, and the stability of the photosensitive transistor 1011 is ensured.

FIG. 11 is another signal timing diagram according to an embodiment of the present disclosure. As shown in FIG. 11, multiple display stages V-display include third display stages V-display3 and fourth display stages V-display4, at least two fourth display stages V-display4 are disposed between adjacent third display stages V-display3; the detection signal V1 has the first voltage in the third display stages V-display3, and in a vertical intermittent stage V-porch with the shortest time interval from a third display stage V-display3, the photocurrent signal is collected. For example, three fourth display stages V-display4 are disposed between adjacent third display stages V-display3, and a voltage of the detection signal V1 in the third display stages V-display3 is different from a voltage of the detection signal V1 in the fourth display stages V-display4 to prevent the photosensitive transistor 1011 from continuously working in the same direction in different stages, thereby reducing the threshold voltage drift of the photosensitive transistor 1011.

The vertical intermittent stage V-porch includes a third vertical intermittent stage V-porch3 located between a third display stage V-display3 and a fourth display stage V-display4 and a fourth vertical intermittent stage V-porch4 located between adjacent fourth display stages V-display4, and the duration of the third vertical intermittent stage V-porch3 is less than the duration of the fourth vertical intermittent stage V-porch4. The photocurrent signal is collected in a light detection stage ALS in the third vertical intermittent stage V-porch3, and no photocurrent signal is collected in a light detection stage ALS in the fourth vertical intermittent stage V-porch4, thereby reducing the collection frequency of an optical signal, reducing an effect of the detection signal V1 on the touch signal in the touch electrode line 102 and ensuring the touch effect.

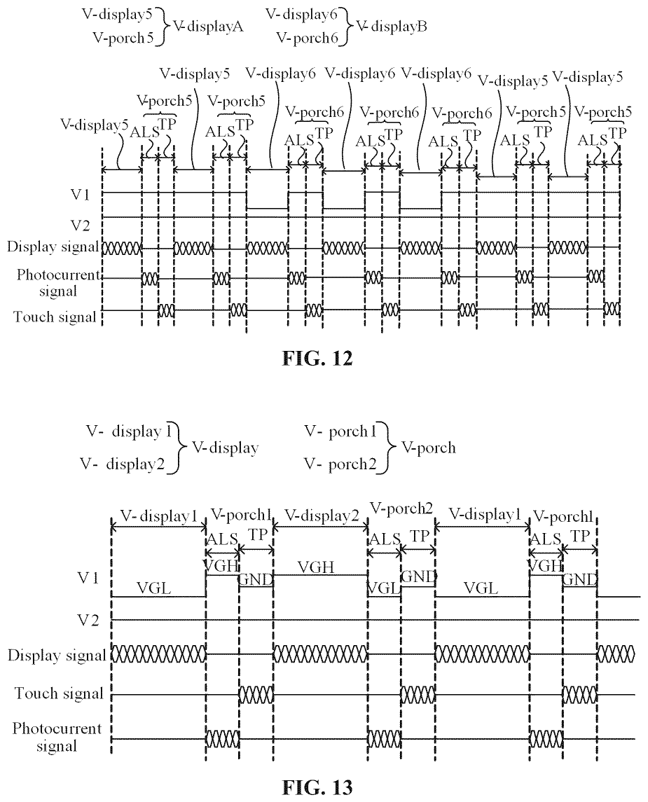

FIG. 12 is another signal timing diagram according to an embodiment of the present disclosure. As shown in FIG. 12, multiple display stages V-display include first display stage groups V-displayA and second display stage groups V-displayB, and the first display stage groups V-displayA and the second display stage groups V-displayB are arranged alternately; the first display stage group V-displayA includes at least two fifth display stages V-display5, and the second display stage group V-displayB includes at least two sixth display stages V-display6; the detection signal V1 has the first voltage in the fifth display stages V-display5, and in a vertical intermittent stage V-porch with the shortest time interval from a fifth display stage V-display5, the photocurrent signal is collected. For example, the first display stage group V-displayA includes two fifth display stages V-display5, the second display stage group V-displayB includes three sixth display stages V-display6, and a voltage of the detection signal V1 in the fifth display stages V-display5 is different from a voltage of the detection signal V1 in the sixth display stages V-display6 to prevent the photosensitive transistor 1011 from continuously working in the same direction in different stages, thereby reducing the threshold voltage drift of the photosensitive transistor 1011.

The vertical intermittent stage V-porch includes a fifth vertical intermittent stage V-porch5 between adjacent fifth display stages V-display5 and a sixth vertical intermittent stage V-porch6 between adjacent sixth display stages V-display6, and the duration of the fifth vertical intermittent stage V-porch5 is less than the duration of the sixth vertical intermittent stage V-porch6. In a light detection stage ALS in the fifth vertical intermittent stage V-porch5, the photocurrent signal is collected, and in the sixth vertical intermittent stage V-porch6, no photocurrent signal is collected. The collection is continuously performed for two frames and is stopped for three frames, thereby reducing the collection frequency of the optical signal, reducing the effect of the detection signal V1 on the touch signal in the touch electrode line 102 and ensuring the touch effect. A ratio of the continuous collection time of the photocurrent signal to the stop collection time of the photocurrent signal may be 1:1, 1:2, 1:3, 2:3, 3:9 or other different ratios, and the collection frequency of the photocurrent signal is adjusted to ensure the touch performance.

Referring to FIGS. 1, 2 and 8, the photosensitive module 101 includes a photosensitive transistor 1011, the detection signal V1 is applied to a first electrode of the photosensitive transistor 1011, the photosensitive transistor 1011 is configured to generate a photocurrent signal according to the detection signal V1 and illumination, and the touch electrode line 102 is configured to transmit a touch signal; a driving stage of the display panel includes display stages V-display and vertical intermittent stages V-porch, the display stages V-display and the vertical intermittent stages V-porch are arranged alternately, and the vertical intermittent stage V-porch include a touch stage TP and a light detection stage ALS; and the touch stage TP does not overlap the light detection stage ALS. In a feasible embodiment, in all touch stages TP, the detection signal V1 has the first voltage. In another feasible embodiment, in some touch stages TP, the detection signal V1 has the first voltage, and in other touch stages TP, the detection signal V1 has a voltage value different from the first voltage. It may be understood that in all the touch stages TP, when the detection signal V1 has the first voltage, both an effect of preventing the detection signal V1 from causing the voltage jump of the touch signal in the touch electrode line 102 and an effect of reducing or even avoiding the generation of the touch noise are beneficial. In at least one light detection stage ALS, the detection signal V1 has a second voltage, and the second voltage is not equal to the first voltage. In a feasible embodiment, in at least one light detection stage ALS, the detection signal V1 has another voltage value other than the second voltage.

For example, as shown in FIG. 8, the first voltage of the detection signal V1 in multiple touch stages TP is the ground voltage GND, and the second voltage in some light detection stages ALS is the gate control negative voltage VGL. The detection signal V1 in light detection stages ALS in different frames may be subjected to a voltage jump. When the second voltage of the detection signal V1 in the light detection stage ALS is the gate control positive voltage VGH, a threshold voltage of the photosensitive transistor 1011 is positively drifted. When the second voltage of the detection signal V1 in the light detection stage ALS is the gate control negative voltage VGL, the threshold voltage of the photosensitive transistor 1011 is negatively drifted. The threshold voltage drift of the photosensitive transistor 1011 can be reduced under a combined action of the gate control positive voltage VGH and the gate control negative voltage VGL and the stability of the photosensitive transistor 1011 can be ensured.

FIG. 13 is another signal timing diagram according to an embodiment of the present disclosure. As shown in FIG. 13, the first voltage of the detection signal V1 in multiple touch stages TP is the ground voltage GND, the first voltage of the detection signal V1 remains consistent and is not subjected to the voltage jump in the multiple touch stages TP, and the touch signal transmitted by the touch electrode line 102 is not affected by the voltage jump of the detection signal V1, thereby reducing or even avoiding a noise generated by the touch signal. The first voltage of the detection signal V1 in the touch stage TP is the ground voltage GND, no threshold voltage drift of the photosensitive transistor 1011 is caused.

The second voltage of the detection signal V1 of some light detection stages ALS is the gate control positive voltage VGH, and the second voltage of the detection signal V1 of some light detection stages ALS is the gate control negative voltage VGL. When the second voltage of the detection signal V1 in the light detection stage ALS is the gate control positive voltage VGH, the threshold voltage of the photosensitive transistor 1011 is positively drifted, and when the second voltage of the detection signal V1 in the light detection stage ALS is the gate control negative voltage VGL, the threshold voltage of the photosensitive transistor 1011 is negatively shifted, thereby effectively reducing the threshold voltage drift of the photosensitive transistor 1011, ensuring the operational stability of the photosensitive transistor 1011 and improving the brightness adjustment accuracy of the display panel. The photocurrent signal may also be collected in a frame-skipping manner, thereby reducing the collection frequency of the photocurrent signal and further reducing the effect on the touch signal.

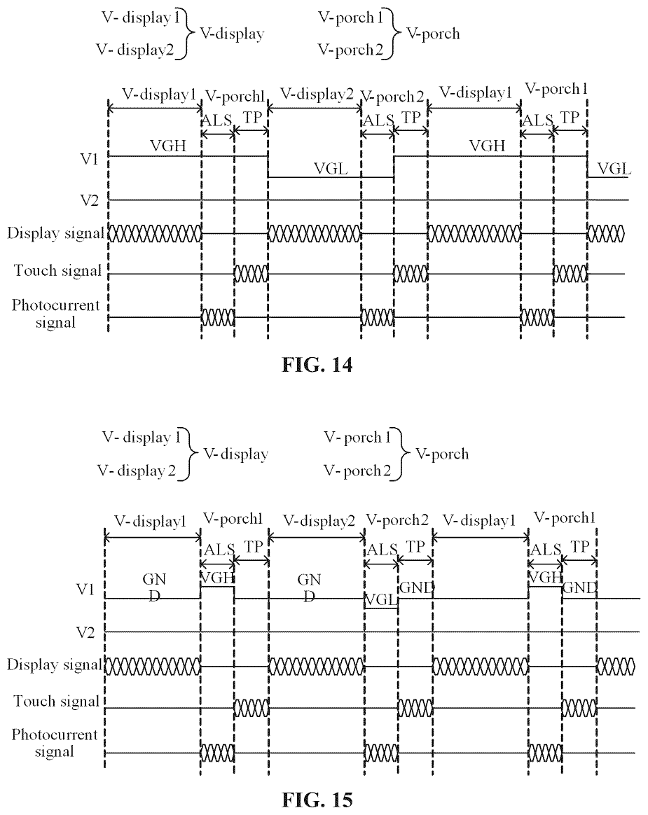

FIG. 14 is another signal timing diagram according to an embodiment of the present disclosure. As shown in FIG. 14, the first voltage of the detection signal V1 in multiple touch stages TP is the gate control positive voltage VGH, the first voltage of the detection signal V1 remains consistent and is not subjected to the voltage jump in the multiple touch stages TP, and the touch signal transmitted by the touch electrode line 102 is not affected by the voltage jump of the detection signal V1, thereby reducing or even avoiding the noise generated by the touch signal.

The second voltage of the detection signal V1 of some light detection stages ALS is the gate control positive voltage VGH, and the second voltage of the detection signal V1 of some light detection stages ALS is the gate control negative voltage VGL. When the second voltage of the detection signal V1 in the light detection stage ALS is the gate control positive voltage VGH, the threshold voltage of the photosensitive transistor 1011 is positively drifted; and when the second voltage of the detection signal V1 in the light detection stage ALS is the gate control negative voltage VGL, the threshold voltage of the photosensitive transistor 1011 is negatively shifted, thereby effectively reducing the threshold voltage drift of the photosensitive transistor 1011, ensuring the operational stability of the photosensitive transistor 1011 and improving the brightness adjustment accuracy of the display panel. A voltage of the detection signal V1 in a display stage V-display remains consistent with a voltage of the detection signal V1 in an adjacent light detection stage ALS, thereby reducing the number of voltage jumps and reducing the operation difficulty of a driver chip.

The display panel includes a pixel driving circuit, and the pixel driving circuit includes a thin-film transistor. The gate control positive voltage VGH and the gate control negative voltage VGL are applied to a gate of the thin-film transistor and are configured to control the thin-film transistor to turn on or off. For an N-type thin-film transistor, the gate control positive voltage VGH is configured to control the thin-film transistor to turn on, and the gate control negative voltage VGL is configured to control the thin-film transistor to turn off. For a P-type thin-film transistor, the gate control positive voltage VGH is configured to control the thin-film transistor to turn off, and the gate control negative voltage VGL is configured to control the thin-film transistor to turn on. The detection signal V1 in light detection stages ALS in different frames may be subjected to a voltage jump. When the second voltage of the detection signal V1 in the light detection stage ALS is the gate control positive voltage VGH, the threshold voltage of the photosensitive transistor 1011 is positively drifted. When the second voltage of the detection signal V1 in the light detection stage ALS is the gate control negative voltage VGL, the threshold voltage of the photosensitive transistor 1011 is negatively drifted. The threshold voltage drift of the photosensitive transistor 1011 can be reduced under a combined action of the gate control negative voltage VGL and the gate control positive voltage VGH and the stability of the photosensitive transistor 1011 can be ensured.

In the display panel in the embodiments of the present disclosure, the detection signal V1 is applied to the first electrode of the photosensitive transistor 1011 of the photosensitive module 101, the photocurrent signal is generated in combination with the illumination, and the display brightness of the display panel is adjusted under different environmental brightness. The driving stage of the display panel includes the display stage V-display and the vertical intermittent stage V-porch that are arranged alternately. The vertical intermittent stage V-porch includes the touch stage TP, and the detection signal V1 in multiple touch stages TP has the same first voltage, thereby avoiding a coupling effect on the touch signal in the touch electrode line 102 caused by the voltage jump of the detection signal V1 and reducing or even avoiding the generation of the touch noise. The first voltage of the detection signal V1 in the touch stage TP is different from the second voltage of the detection signal V1 in at least one light detection stage ALS, and the detection signal V1 in different light detection stages ALS has a voltage jump, thereby reducing or even avoiding the threshold voltage drift of the photosensitive transistor 1011, ensuring the stable operation of the photosensitive transistor 1011 and improving the accuracy of the photosensitive collection.

FIG. 15 is another signal timing diagram according to an embodiment of the present disclosure. As shown in FIG. 15, in the display stages V-display, the detection signal V1 has the first voltage. A voltage of the detection signal V1 in the display stage V-display is equal to a voltage of the detection signal V1 in the touch stage TP. For example, the first voltage is output to the photosensitive transistor 1011 in both the display stage V-display and the touch stage TP. The first voltage is the ground voltage GND, and no drift is caused to the threshold voltage of the photosensitive transistor 1011, thereby ensuring the stability of the photosensitive transistor 1011.

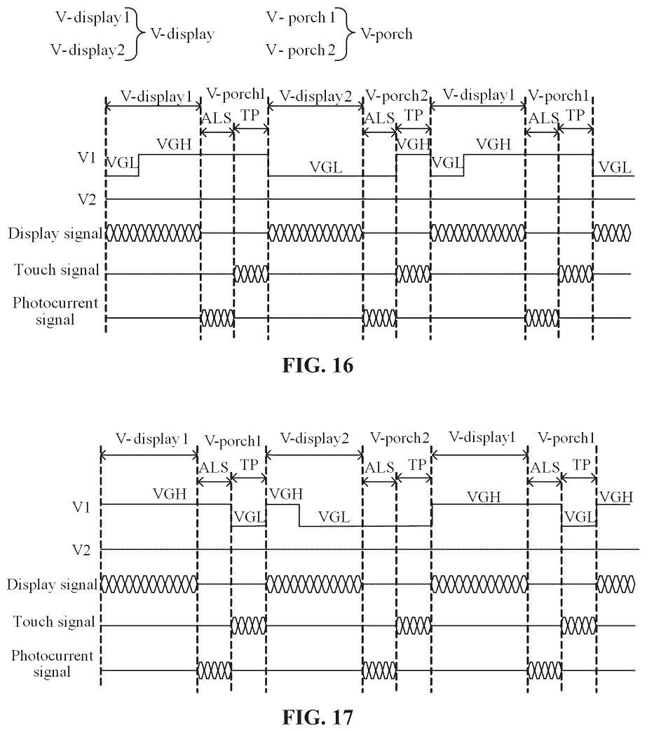

The detection signal V1 in some display stages V-display may also be subjected to voltage switching. FIG. 16 is another signal timing diagram according to an embodiment of the present disclosure. FIG. 17 is another signal timing diagram according to an embodiment of the present disclosure. As shown in FIG. 16, the first voltage of the detection signal V1 in multiple touch stages TP is the gate control positive voltage VGH, or as shown in FIG. 17, the first voltage of the detection signal V1 in multiple touch stages TP is the gate control negative voltage VGL. In the multiple touch stages TP, the first voltage of the detection signal V1 remains consistent and is not subjected to the voltage jump, and the touch signal transmitted by the touch electrode line 102 is not affected by the voltage jump of the detection signal V1, thereby reducing or even avoiding the noise generated by the touch signal. The driving stage of the display panel includes a positive frame and a negative frame, and the duration for a voltage of the detection signal V1 in the positive frame being the gate control positive voltage VGH is equal to the duration for a voltage of the detection signal V1 in the negative frame being the gate control negative voltage VGL so that the durations of different driving stages of the display panel remain consistent, thereby ensuring the display effect.

Referring to FIG. 13, multiple vertical intermittent stages V-porch include first vertical intermittent stages V-porch1 and second vertical intermittent stages V-porch2, and the first vertical intermittent stages V-porch1 and the second vertical intermittent stages V-porch2 are arranged alternately. In a light detection stage ALS in the first vertical intermittent stage V-porch1, the detection signal V1 has the second voltage, and in a light detection stage ALS in the second vertical intermittent stage V-porch2, the detection signal V1 has a third voltage; an absolute value of the second voltage is equal to an absolute value of the third voltage, and the second voltage and the third voltage have opposite polarities. When the detection signal V1 always remains working in the same direction in the vertical intermittent stages V-porch, the photosensitive transistor 1011 is prone to the threshold voltage drift, the detection signal V1 in light detection stage ALSs in adjacent vertical intermittent stages V-porch is adjusted for voltage switching, the second voltage of the detection signal V1 in the light detection stage ALS in the first vertical intermittent stage V-porch1 is not equal to the third voltage of the detection signal V1 in the light detection stage ALS in the second vertical intermittent stage V-porch2, and the absolute value of the second voltage is equal to the absolute value of the third voltage. The second voltage is the gate control positive voltage VGH, and the third voltage is the gate control negative voltage VGL. When the second voltage of the detection signal V1 in the light detection stage ALS in the first vertical intermittent stage V-porch1 is the gate control positive voltage VGH, the threshold voltage of the photosensitive transistor 1011 is positively drifted. When the third voltage of the detection signal V1 in the light detection stage ALS in the second vertical intermittent stage V-porch2 is the gate control negative voltage VGL, the threshold voltage of the photosensitive transistor 1011 is negatively drifted, and the threshold voltage drift of the photosensitive transistor 1011 can be reduced or even avoided under a combined action of the second voltage and the third voltage and the stability of the photosensitive transistor 1011 can be ensured.

Referring to FIG. 1, the display panel further includes the detection signal line 103, the detection signal line 103 is located in the non-display region NAA, is electrically connected to the first electrode of the photosensitive transistor 1011 and transmits the detection signal V1 to the photosensitive transistor 1011, and the photosensitive transistor 1011 generates the photocurrent signal according to the detection signal V1 and the illumination and adjusts the brightness of the display panel according to the photocurrent signal.

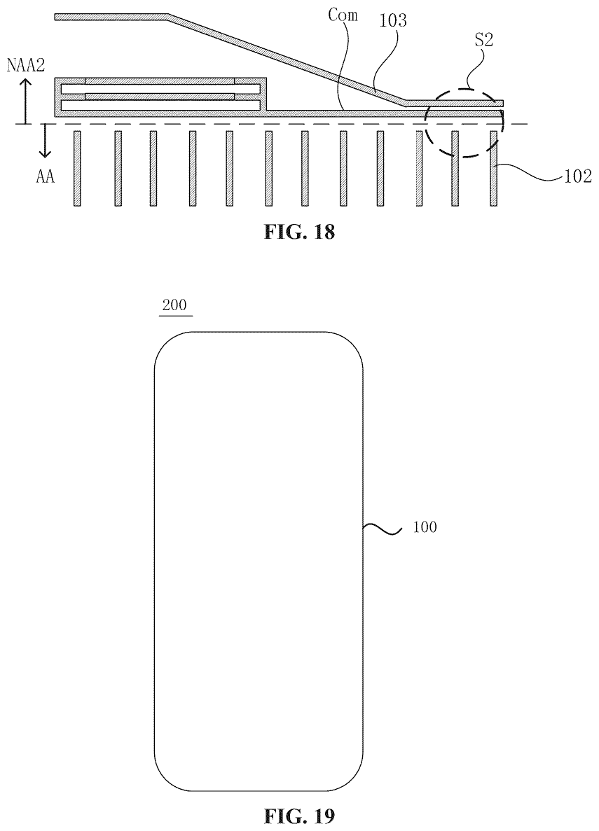

FIG. 18 is an enlarged structure diagram of region S1 of FIG. 1. Referring to FIGS. 1 and 18, the display panel includes a display region AA and a bottom side non-display region NAA1, the bottom side non-display region NAA1 is located on one side of the display region AA, at least a portion of the detection signal line 103 is located in the bottom side non-display region NAA1, and at least a portion of the touch electrode line 102 is located in the bottom side non-display region NAA1. The display panel further includes a top side non-display region NAA2, the top side non-display region NAA2 and the bottom side non-display region NAA1 are located on two opposite sides of the display region AA. The touch electrode line 102 extends from the bottom side non-display region NAA1 to the display region AA and is electrically connected to the touch electrode (not shown in FIG. 1) in the display region AA. At least a portion of the detection signal line 103 is located in the bottom side non-display region NAA1 and extends from the bottom side non-display region NAA1 to the top side non-display region NAA2. An end of the touch electrode line 102 away from the bottom side non-display region NAA1 is adjacent to the detection signal line 103 in the top side non-display region NAA2, especially for region S2 shown in FIG. 18. Since the spacing between the detection signal line 103 and the touch electrode line 102 is relatively short, when the detection signal V1 in the detection signal line 103 is subjected to a voltage jump, the coupling occurs between the detection signal line 103 and the touch electrode line 102, resulting in the touch noise in the display panel. The detection signal V1 is adjusted to have the same voltage value in the touch stages TP, and the voltage value of the detection signal V1 is prevented from being switched back and forth in multiple touch stages TP. Therefore, in the touch stages TP, the touch signal transmitted by the touch electrode line 102 is not affected by the voltage jump of the detection signal V1, thereby reducing or even avoiding a noise generated by the touch signal.

For example, referring to FIGS. 1 and 18, a direction from the bottom side non-display region NAA1 to the top side non-display region NAA2 is consistent with an extending direction of the touch electrode line 102 in the display region AA. The display panel further includes a common electrode line Com. The common electrode line Com is configured to provide a common voltage, and the common voltage may include, for example, 0 V. In other embodiments, the common voltage may also have other values. At least a portion of the common electrode line Com is located in the top side non-display region NAA2. At least a portion of the detection signal line 103 is located in the top side non-display region NAA2. Since coupling easily occurs between the detection signal line 103 and the touch electrode line 102 that are disposed in the same layer, the solution provided in the embodiments of the present disclosure that “the voltage value of the detection signal V1 is prevented from being switched back and forth in multiple touch stages TP” is particularly suitable for the preceding case.

For example, referring to FIGS. 1 and 18, the display panel includes a pixel driving circuit, and the pixel driving circuit includes a thin-film transistor. At least a portion of the common electrode line Com is disposed in the same layer with a gate of the thin-film transistor. The detection signal line 103, the touch electrode line 102, and both a source and a drain of the thin-film transistor are disposed in the same layer.

Referring to FIG. 1, the display panel further includes a top side non-display region NAA2, where the top side non-display region NAA2 and the bottom side non-display region NAA1 are located on two opposite sides of the display region AA, and the photosensitive module 101 is located in the top side non-display region NAA2. The photosensitive module 101 is used for sensing the external ambient light and generating the photocurrent signal in combination with the detection signal V1 output by the detection signal line 103 to accurately adjust the brightness of the display panel according to different ambient brightness.

Referring to FIG. 1, the display panel further includes a side non-display region NAA3, the side non-display region NAA3 is connected to the top side non-display region NAA2 and the bottom side non-display region NAA1, and at least a portion of the detection signal line 103 is located in the side non-display region NAA3. The detection signal line 103 extends to the top side non-display region NAA2 via the bottom side non-display region NAA1 and the side non-display region NAA3 and is connected to the photosensitive module 101 in the top side non-display region NAA2.

Referring to FIGS. 1 and 2, the display panel further includes a first detection output signal line Vout1 and at least three second detection output signal lines, and the second detection output signal lines include a first sub-second detection output signal line Vout2, a second sub-second detection output signal line Vout3 and a third sub-second detection output signal line Vout4. The display panel further includes detection resistors, the first detection output signal line Vout1 is electrically connected to a first detection resistor R1, the first sub-second detection output signal line Vout2 is electrically connected to a second detection resistor R2, the second sub-second detection output signal line Vout3 is electrically connected to a third detection resistor R3, and the third sub-second detection output signal line Vout4 is electrically connected to a fourth detection resistor R4. A magnitude of a resistance of the detection resistor is adjusted so that voltage values of the photocurrent signal and the reference signal reach a detection range of the driver chip.

The photosensitive module 101 includes a first photosensitive transistor 11 and three second photosensitive transistors 12 that are connected in parallel, and the first photosensitive transistors 11 and the second photosensitive transistors 12 may be formed in the same process with the thin-film transistor of the pixel driving circuit in the display panel, thereby saving a preparation cost.

The detection signal line 103 is connected to a first electrode of the first photosensitive transistor 11 and a first electrode of the second photosensitive transistor 12. A second electrode of the first photosensitive transistor 11 is electrically connected to the first detection output signal line Vout1, and a second electrode of the second photosensitive transistor 12 is electrically connected to the second detection output signal line. A control signal is applied to a gate of the first photosensitive transistor 11 and a gate of the second photosensitive transistor 12, and the control signal is generally a fixed potential signal. The active layer of the photosensitive transistor 1011 includes a photosensitive material layer, and a light-shielding element 1012 shields the photosensitive material layer of the first photosensitive transistor 11 so that the first photosensitive transistor 11 is not affected by the external ambient light. After receiving the detection signal V1 output by the detection signal line 103, the first electrode of the first photosensitive transistor 11 generates a leakage current, that is, the reference signal, and the leakage current is output via the second electrode of the first photosensitive transistor 11 and the first detection output signal line in sequence.

Instead of being shielded by the light-shielding element 1012, an active layer of the second photosensitive transistor 12 receives the irradiation of the ambient light and generates the photocurrent signal in combination with the detection signal V1 received by the first electrode of the second photosensitive transistor 12 and output by the detection signal line 103, and the photocurrent signal is output via the second electrode of the second photosensitive transistor 12 and the second detection output signal in sequence.

The display panel may further include a brightness control module (not shown in the figure). The brightness control module is disposed in the bottom side non-display region NAA1 of the display panel. The brightness control module may be disposed in the driver chip. The brightness control module is electrically connected to the first detection output signal line and the second detection output signal line for comparing the reference signal with the photocurrent signal to obtain a photo-generated current generated when the second photosensitive transistor 12 is subjected only to the irradiation of the ambient light, and the actual brightness of the ambient light is obtained according to the photo-generated current, thereby improving the accurate adjustment of the brightness of the display panel.

FIG. 19 is a structure diagram of a display device according to an embodiment of the present disclosure. As shown in FIG. 19, the display device 200 includes the display panel 100 described in the preceding embodiments.

It is to be noted that the display device provided in the embodiment has the same or corresponding beneficial effects of the display panel of the preceding embodiments, which is not repeated here. The display device 200 provided in embodiments of the present disclosure may be the phone shown in FIG. 19, or may be any electronic product having a display function, including, but not limited to the following categories: a television, a laptop, a desktop display, a tablet computer, a digital camera, a smart bracelet, smart glasses, a vehicle-mounted display, a medical device, an industrial control device, a touch interactive terminal, and no limitations are made thereto in embodiments of the present disclosure.

The preceding embodiments do not limit the scope of the present disclosure. It is to be understood by those skilled in the art that various modifications, combinations, sub-combinations, and substitutions may be performed according to design requirements and other factors. Any modification, equivalent substitution, improvement, or the like made within the spirit and principle of the present disclosure is within the scope of the present disclosure.

What is claimed is:

1. A display panel, comprising a photosensitive module and a touch electrode line, wherein the photosensitive module comprises a photosensitive transistor, wherein a detection signal is applied to a first electrode of the photosensitive transistor, the photosensitive transistor is configured to generate a photocurrent signal according to the detection signal and illumination, and the touch electrode line is configured to transmit a touch signal;
a driving stage of the display panel comprises display stages and vertical intermittent stages, wherein the display stages and the vertical intermittent stages are arranged alternately, and a vertical intermittent stage of the vertical intermittent stages comprises a touch stage; and
in a plurality of touch stages, the detection signal has a first voltage, and in at least one of the display stages, the detection signal has a second voltage, wherein the second voltage and the first voltage are not identical.

2. The display panel according to claim 1, wherein the vertical intermittent stage further comprises a light detection stage, and the detection signal has the first voltage in the light detection stage.

3. The display panel according to claim 2, wherein the light detection stage overlaps the touch stage.

4. The display panel according to claim 1, wherein the first voltage and the second voltage have opposite polarities.

5. The display panel according to claim 4, wherein the display stages comprise first display stages and second display stages, wherein the first display stages and the second display stages are arranged alternately; and
the detection signal has the first voltage in the first display stages, and the detection signal has the second voltage in the second display stages;
wherein an absolute value of the first voltage is equal to an absolute value of the second voltage.

6. The display panel according to claim 1, wherein the display stages comprise first display stages and second display stages, and the vertical intermittent stages comprise first vertical intermittent stages and second vertical intermittent stages, wherein the first display stages, the first vertical intermittent stages, the second display stages and the second vertical intermittent stages are respectively arranged in sequence; and
a voltage of the detection signal in the first vertical intermittent stages is the same as a voltage of the detection signal in the first display stages, and the photocurrent signal is collected in the first vertical intermittent stages.

7. The display panel according to claim 1, wherein the vertical intermittent stage further comprises a light detection stage; and
the detection signal has the second voltage in at least one light detection stage.

8. The display panel according to claim 7, wherein the display stages comprise first display stages and second display stages, wherein the first display stages and the second display stages are arranged alternately; and
the detection signal has the second voltage in the first display stages, and the detection signal has a third voltage in the second display stages, wherein the first voltage, the second voltage and the third voltage are not identical;
wherein the second voltage is greater than the third voltage; and
an absolute value of the second voltage is equal to an absolute value of the third voltage, and the second voltage and the third voltage have opposite polarities; or the third voltage is in a high-impedance state.

9. The display panel according to claim 8, wherein the vertical intermittent stages comprise first vertical intermittent stages and second vertical intermittent stages, wherein the first display stages, the first vertical intermittent stages, the second display stages and the second vertical intermittent stages are respectively arranged in sequence; and
the detection signal has the second voltage in the first vertical intermittent stages, and the detection signal has the third voltage in the second vertical intermittent stages;
wherein a light detection stage in a first vertical intermittent stage of the first vertical intermittent stages is located between a touch stage in the first vertical intermittent stage and a first display stage before the first vertical intermittent stage; and
a light detection stage in a second vertical intermittent stage of the second vertical intermittent stages is located between a touch stage in the second vertical intermittent stage and a second display stage before the second vertical intermittent stage.

10. The display panel according to claim 1, wherein the first voltage is a ground voltage.

11. The display panel according to claim 1, wherein the display stages comprise third display stages and fourth display stages, wherein at least two of the fourth display stages are disposed between adjacent third display stages among the third display stages; and
the detection signal has the first voltage in the third display stages, and in a vertical intermittent stage among the vertical intermittent stages with a shortest time interval from a third display stage among the third display stages, the photocurrent signal is collected.

12. The display panel according to claim 1, wherein the display stages comprise first display stage groups and second display stage groups, wherein the first display stage groups and the second display stage groups are arranged alternately;
a first display stage group of the first display stage groups comprises at least two fifth display stages, and a second display stage group of the second display stage groups comprises at least two sixth display stages; and
the detection signal has the first voltage in the at least two fifth display stages, and in a vertical intermittent stage among the vertical intermittent stages with a shortest time interval from a fifth display stage among the at least two fifth display stages, the photocurrent signal is collected.

13. The display panel according to claim 1, comprising a thin-film transistor;
wherein at least one of the first voltage and the second voltage is less than a gate control positive voltage, and the gate control positive voltage is configured to control the thin-film transistor to turn on or off.

14. The display panel according to claim 1, further comprising a detection signal line, wherein the detection signal line is electrically connected to the first electrode of the photosensitive transistor and configured to transmit the detection signal.

15. The display panel according to claim 14, comprising a display region, a bottom side non-display region and a top side non-display region, wherein the top side non-display region and the bottom side non-display region are located on two opposite sides of the display region;
at least a portion of the detection signal line is located in the bottom side non-display region and extends from the bottom side non-display region to the top side non-display region, and at least a portion of the touch electrode line is located in the bottom side non-display region and extends from the bottom side non-display region to the display region; and
an end of the touch electrode line away from the bottom side non-display region is adjacent to the detection signal line in the top side non-display region;
wherein the photosensitive module is located in the top side non-display region;
wherein the display panel further comprises a side non-display region, the side non-display region is connected to the top side non-display region and the bottom side non-display region; and at least a portion of the detection signal line is located in the side non-display region.

16. The display panel according to claim 14, further comprising a first detection output signal line and at least one second detection output signal line; wherein
the photosensitive module comprises at least two photosensitive transistors and a light-shielding element, wherein the at least two photosensitive transistors comprise a first photosensitive transistor and a second photosensitive transistor, wherein a second electrode of the first photosensitive transistor is electrically connected to the first detection output signal line, and a second electrode of the second photosensitive transistor is electrically connected to the at least one second detection output signal line; and
the light-shielding element shields a photosensitive material layer of the first photosensitive transistor.

17. A display panel, comprising a photosensitive module and a touch electrode line, wherein the photosensitive module comprises a photosensitive transistor, wherein a detection signal is applied to a first electrode of the photosensitive transistor, the photosensitive transistor is configured to generate a photocurrent signal according to the detection signal and illumination, and the touch electrode line is configured to transmit a touch signal;
a driving stage of the display panel comprises display stages and vertical intermittent stages, wherein the display stages and the vertical intermittent stages are arranged alternately, and a vertical intermittent stage of the vertical intermittent stages comprises a touch stage and a light detection stage; and
in a plurality of touch stages, the detection signal has a first voltage, and in at least one light detection stage, the detection signal has a second voltage, wherein the second voltage and the first voltage are not identical.

18. The display panel according to claim 17, wherein the detection signal has the first voltage in the display stages.

19. The display panel according to claim 18, wherein the vertical intermittent stages comprise first vertical intermittent stages and second vertical intermittent stages, wherein the first vertical intermittent stages and the second vertical intermittent stages are arranged alternately;
in a light detection stage in the first vertical intermittent stages, the detection signal has the second voltage, and in a light detection stage in the second vertical intermittent stages, the detection signal has a third voltage; and
an absolute value of the second voltage is equal to an absolute value of the third voltage, and the second voltage and the third voltage have opposite polarities.

20. A display device, comprising a display panel; wherein the display panel comprises a photosensitive module and a touch electrode line, wherein the photosensitive module comprises a photosensitive transistor, wherein a detection signal is applied to a first electrode of the photosensitive transistor, the photosensitive transistor is configured to generate a photocurrent signal according to the detection signal and illumination, and the touch electrode line is configured to transmit a touch signal;
a driving stage of the display panel comprises display stages and vertical intermittent stages, wherein the display stages and the vertical intermittent stages are arranged alternately, and a vertical intermittent stage of the vertical intermittent stages comprises a touch stage; and
in a plurality of touch stages, the detection signal has a first voltage, and in at least one of the display stages, the detection signal has a second voltage, wherein the second voltage and the first voltage are not identical.
